(19) United States
(12) Patent Application Publication
(10) Pub. No.: US 2017/0200839 A1
(43) Pub. Date: Jul. 13, 2017

(54) SOLAR CELL, METHOD FOR MANUFACTURING SAME, SOLAR CELL MODULE, AND METHOD FOR MANUFACTURING SAME

(71) Applicant: Kaneka Corporation, Osaka (JP)

(72) Inventors: Kunihiro Nakano, Osaka (JP); Kunta Yoshikawa, Osaka (JP); Daisuke Adachi, Osaka (JP)

(73) Assignee: Kaneka Corporation, Osaka (JP)

(21) Appl. No.: 15/473,000

(22) Filed: Mar. 29, 2017

Related U.S. Application Data
(63) Continuation of application No. PCT/JP2015/074656, filed on Aug. 31, 2015.

(30) Foreign Application Priority Data
Sep. 30, 2014 (JP) 2014-202431

(51) Int. Cl. H01L 31/0224; H01L 31/0236; H01L 31/18

(52) U.S. Cl. CPC H01L 31/022466; H01L 31/1804; H01L 31/1884; H01L 31/02366

(57) ABSTRACT

A solar cell is provided with an electrode layer on a photovoltaic conversion section including a crystalline silicon substrate. Deposition of the electrode layer is performed by a deposit-up method with a substrate being mounted in such a manner that an opening edge portion of a mask plate having an opening is in contact with the substrate. The opening edge portion of the mask plate has a tapered surface at a part that is in contact with first principal surface of the substrate, the tapered surface conforming to a deflection angle at a peripheral end of the substrate. A solar cell having a large effective area can be prepared by suppressing deposition of electrode layer on mask-covered region due to penetration.

### TECHNICAL FIELD

One or more embodiments of the present invention relate to solar cell and method for manufacturing thereof. One or more embodiments of the present invention also relate to solar cell module and method for manufacturing thereof.

### BACKGROUND

In a solar cell, carriers (electrons and holes) generated by light irradiation to a photoelectric conversion section including a semiconductor junction or the like are extracted to an external circuit to generate electricity. Crystalline silicon solar cell having conductive silicon-based thin-films on both sides of a single-crystalline silicon substrate is called heterojunction solar cell. Among heterojunction solar cells, one having an n-type silicon-based thin-film on one side of a crystalline silicon substrate, a p-type silicon-based thin-film on the other side of the crystalline silicon substrate and an intrinsic silicon-based thin-film between conductive (n-type or p-type) silicon-based thin-film and the crystalline silicon substrate is known as one embodiment of a crystalline silicon solar cell with a high conversion efficiency.

The heterojunction solar cell has a transparent electrode layer on a photoelectric conversion section including a conductive silicon-based thin-film on both surfaces of a single-crystalline silicon substrate. The transparent electrode layer acts to transport photogenerated carriers at the photoelectric conversion section to a metal collecting electrode. The transparent electrode layer is formed by a chemical vapor deposition (CVD) method or a physical vapor deposition (PVD) method such as a sputtering method or an ion plating method. The transparent electrode layer is formed not only on the surface of the substrate but also formed on the side surfaces and the back surface of the substrate in a wraparound manner, and therefore the transparent electrode layers on both sides come into contact with each other, leading to occurrence of an electrical short-circuit between the front surface and the back surface.

For preventing an electrical short-circuit between the transparent electrode layers on front and back surfaces, a method is known in which a transparent electrode layer is formed while the peripheral end of a crystalline silicon substrate is covered with a mask as disclosed in Patent Document 1 and Patent Document 2.

### PRIOR ART DOCUMENTS

### Patent Documents

Patent Document 1: Japanese Patent Laid-open Publication No. 2001-44461
Patent Document 2: International Publication No. WO 2013/161127

When deposition is performed while a mask is used for preventing deposition of an electrode layer on the end portions and side surfaces of a substrate in manufacturing of a solar cell including an electrode layer on a silicon substrate, such as a heterojunction solar cell, vapor deposition particles penetrate from an air gap between the substrate and the mask to be deposited on a mask-covered region if the substrate and the mask are not sufficiently adhered to each other. In a region where the electrode layer is deposited in an air gap portion of the mask-covered region by penetration, the covering ratio and the thickness of the electrode layer tend to be smaller as compared to other regions (regions which are not covered with the mask and have a constant thickness) (hereinafter, a region where at least one of the thickness and the covering ratio is smaller as compared to other regions is sometimes referred to as a “transition region”).

In the transition region, the resistance of the electrode layer, and the reflectivity associated with multiple interference at the interface are high, and therefore solar cell characteristics tend to be deteriorated when the width of the transition region increases. When the transition region extends to the peripheral end and the side surfaces of the substrate, a short circuit with the electrode layer on the back side easily occurs. Therefore, the width of the transition region may be as small as possible.

In a crystalline silicon solar cell such as a heterojunction solar cell, a crystalline silicon substrate having surface textures is used for improving light-capturing efficiency to a photoelectric conversion section. Accordingly, an air gap is inevitably generated between the recess portion of the texture and the mask, so that it is difficult to completely adhere the substrate and the mask to each other. Accordingly, it is required that the effective power generation area of the solar cell be increased while the transition region of the electrode layer is made as small as possible to prevent a short-circuit on both sides even when the substrate surface has textures.

### SUMMARY

In one or more embodiments of the present invention, a substrate is mounted on a mask plate having a tapered surface at an opening edge portion, and an electrode layer is formed by a deposit-up (face-down) method in which deposition is performed from the lower side to the upper side in a vertical direction.

One or more embodiments of the present invention relate to a method for manufacturing a solar cell including a first electrode layer on a first principal surface of a photoelectric conversion section including a crystalline silicon substrate. In one or more embodiments, in a step (first electrode layer forming step) of forming a first electrode layer on a first principal surface side of a crystalline silicon substrate, deposition is performed by a deposit-up method with the crystalline silicon substrate mounted in such a manner that an opening edge portion of a mask plate having an opening is in contact with the first principal surface side of the crystalline silicon substrate. A transparent electrode layer is not formed at the peripheral end of the first principal surface of the photoelectric conversion section because deposition is performed while the peripheral edge of the first principal surface is in contact with a mask. Accordingly, electrodes on front and back sides are insulated from each other.

In one or more embodiments, the opening edge portion of the mask plate has a tapered surface at a part that is in contact with the substrate. When the tapered surface is set so as to conform to the deflection angle θ at the peripheral end of the substrate, the number of contact points between the mask plate and the substrate increases, leading to a reduction in air gap in the mask-covered region. As a result, an area where vapor deposition particles penetrate into the mask-covered region is reduced, so that the width of an electrode layer-transition region becomes small. The width of the transition region may be less than 1.5 mm.

An angle α formed by a mounting plane of the mask plate and the tapered surface may be in the range of 0.5 times to 2 times as large as the deflection angle θ of the silicon substrate at the peripheral end. The deflection angle θ of the silicon substrate at the peripheral end is, for example, within the range of 0.1° to 10°. When the substrate mounted on the mask plate is deflected under the self-weight, the substrate is deflected so as to project on the first principal surface side (lower side), the first principal surface being a deposition surface.

In one or more embodiments of the solar cell of the present invention, the photoelectric conversion section includes a conductive silicon-based thin-film on both surfaces of a single-crystalline silicon substrate having a textured surface. The first electrode layer on the light-receiving side is a transparent electrode layer, and a second electrode layer is formed on the back side of the photoelectric conversion section. In this embodiment, the first electrode layer is not formed at the peripheral end of the first principal surface of the photoelectric conversion section, and thus the first electrode layer and the second electrode layer are insulated from each other. The second electrode layer may also be formed at the peripheral end of the photoelectric conversion section on the second principal surface side, and on the side surfaces of the photoelectric conversion section. The second electrode layer may also be formed at the peripheral end of the first principal surface side. In this case, the shortest distance between the first electrode layer and the second electrode layer (width of the insulating region) may be more than 0 and less than 1.5 mm on the first principal surface.

In one or more embodiments, a pattern-shaped collecting electrode is formed on the electrode layer on the light-receiving side. The patterned collecting electrode can be formed by, for example, a plating method. When a pattern-shaped metal seed is formed on the first electrode layer, an insulating layer is then formed on the whole surface of the first electrode layer, and the insulating layer on the metal seed is provided with an aperture, a metal electrode that is in conduction with the metal seed through the aperture can be formed by a plating method.

The solar cell is sealed with a sealing material to form a solar cell module.

In the method according one or more embodiments of the present invention, an electrode layer is formed by a deposit-up method with a substrate mounted on a tapered surface of an opening edge portion of a mask plate, leading to a reduction in air gap between the substrate and the mask plate in a mask-covered region. Accordingly, even when the substrate is deflected, the width of an electrode layer-transition region can be reduced, and the effective area of a solar cell can be increased. Since the mask plate has a tapered surface, alignment of the mask plate is facilitated to improve productivity, and the handling characteristics of the substrate are improved, so that even when the substrate has a small thickness, defects such as cracking and chipping can be suppressed.

### BRIEF DESCRIPTION OF THE DRAWINGS

FIG. 1 is a schematic sectional view of a solar cell according to one or more embodiments of the present invention.

FIG. 2 is a schematic perspective view of one form of a mask plate to be used in electrode layer deposition according to one or more embodiments of the present invention.

FIG. 3 is a schematic sectional view showing one example of a state in which a substrate is mounted on a mask plate according to one or more embodiments of the present invention.

FIG. 4 is a schematic sectional view showing one example of a state in which a substrate is mounted on a mask plate according to one or more embodiments of the present invention.

FIGS. 5A to 5F are schematic sectional views each showing shape of opening edge portion of mask plate.

### DETAILED DESCRIPTION OF EMBODIMENTS

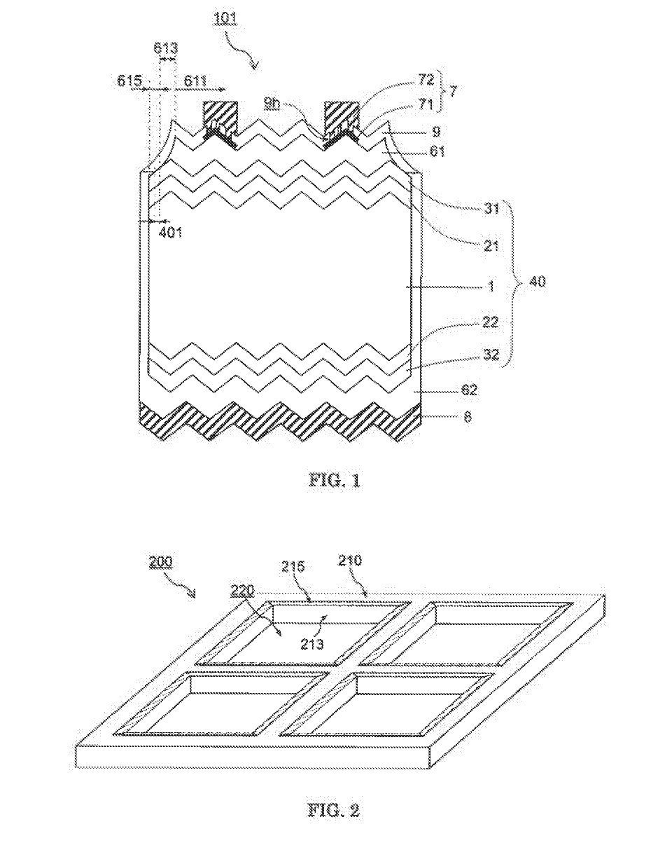

FIG. 1 is a schematic sectional view of a heterojunction solar cell according to one or more embodiments of the present invention. A heterojunction solar cell 101 includes a first electrode layer 61 on one surface of a photoelectric conversion section 40, and a second electrode layer 62 on the other surface of the photoelectric conversion section 40. In the heterojunction solar cell 101, each of the first electrode layer 61 and the second electrode layer 62 is a transparent electrode layer. The first electrode layer 61 is not formed at the peripheral end of the first principal surface of the photoelectric conversion section 40, and an electrode layer-non-formed region 615 exists at the peripheral edge of the first principal surface. In one or more embodiments of the present invention, the first electrode layer is formed while the peripheral edge of the substrate is covered with a mask, so that the electrode layer-non-formed region is provided. In this specification, the “peripheral end” refers to the end edge of the principal surface. The “peripheral edge” refers to the peripheral end and a region extending over a certain distance (e.g., several tens μm to several mm) from the peripheral end.

[Photoelectric Conversion Section]

The photoelectric conversion section 40 of the heterojunction solar cell 101 includes a first conductive silicon-based thin-film 31 and a second conductive silicon-based thin-film 32 on the first principal surface and the second principal surface, respectively, of a single-crystalline silicon substrate 1. The conductivity-type of one of these conductive silicon-based thin-films is a p-type, and the conductivity-type of the other conductive silicon-based thin-film is an n-type.

The conductivity-type of the single-crystalline silicon substrate 1 may be an n-type or a p-type. In comparison between electron and hole, electron has a higher mobility, and thus when the silicon substrate 1 is an n-type single-crystalline silicon substrate, the conversion characteristic is particularly high. The silicon substrate 1 has textures on at least the light-receiving side, or on both sides. Textures are formed using, for example, an anisotropic etching technique. Textures formed by anisotropic etching have tetragonal pyramid-shaped irregularity structures.

In one or more embodiments, the height difference of the texture is about 0.5 μm to 40 μm, or 1 μm to 20 μm. When the height difference of the texture is within a range as described above, the optical path length of light in a wavelength region of 300 to 1200 nm, which can be absorbed by a single-crystalline silicon, is increased by light scattering, and light is effectively scattered by irregularity structures, so that the effect of reducing interface reflection is efficiently obtained. The height difference of the texture may be 10 μm or less, or 5 μm or less. By reducing the height difference of the texture, penetration of vapor deposition particles from an air gap in deposition with a mask can be reduced.

In one or more embodiments, the thickness of the silicon substrate 1 is not particularly limited, but it may be 10 μm to 150 μm, or 30 μm to 120 μm. When the thickness of the silicon substrate is 150 μm or less, the use amount of silicon decreases, and therefore costs can be reduced. As the thickness of the silicon substrate decreases, recombination of photogenerated carriers in the silicon substrate is reduced, and therefore the open circuit voltage (Voc) of the solar cell tends to be improved. The thickness of the silicon substrate can be defined by a distance between the peak of the projection portion of the texture on the front side and the peak of the projection portion of the texture on the back side.

The photoelectric conversion section 40 may include an intrinsic silicon-based thin-film 21 between the single-crystalline silicon substrate 1 and the conductive silicon-based thin-film 31, and an intrinsic silicon-based thin-film 22 between the single-crystalline silicon substrate 1 and the conductive silicon-based thin-film 32. By providing the intrinsic silicon-based thin-film on the surface of the single-crystalline silicon substrate, surface passivation can be effectively performed while diffusion of impurities to the single-crystalline silicon substrate is suppressed. For effectively performing surface passivation of the single-crystalline silicon substrate 1, the intrinsic silicon-based thin-films 21 and 22 may be intrinsic amorphous silicon thin-films.

Deposition method for forming silicon-based thin-films 21 and 22 may be a plasma-enhanced CVD method. Deposition conditions used for forming silicon-based thin-films by a plasma-enhanced CVD method may be as follows: a substrate temperature of 100 to 300° C.; a pressure of 20 to 2600 Pa; and a high-frequency power density of 0.004 to 0.8 W/cm². A source gas used to form the silicon-based thin-films may be a mixed gas of H₂ and silicon-containing gas such as SiH₄ or Si₂H₆.

As the conductive silicon-based thin-films 31 and 32 of p-type or n-type, amorphous silicon, microcrystalline silicon (material including amorphous silicon and crystalline silicon), amorphous silicon alloy and microcrystalline silicon alloy may be used. Examples of the silicon alloy include silicon oxide, silicon carbide, silicon nitride silicon germanium and the like. Among the above, conductive silicon-based thin-film may be an amorphous silicon thin-film.

As with the intrinsic silicon-based thin-films, the conductive silicon-based thin-films 31 and 32 may be formed by a plasma-enhanced CVD method. In deposition of a conductive silicon-based thin-film, a dopant gas such as B₂H₆ or PH₃ is used for adjusting conductivity type (p-type or the n-type). The amount of conductivity-type determining impurity is sufficient to be a trace amount; thus, a mixed gas diluted with SiH₄ or H₂ beforehand may be used. When a gas containing a different element, such as CH₄, CO₂, NH₃ or GeH₄, is added thereto in formation of the conductive silicon-based thin-film, silicon is alloyed so that the energy gaps of the conductive silicon-based thin-films can be changed.

[Electrode Layer]

On the conductive silicon-based thin-films 31 and 32 of the photoelectric conversion section 40, transparent electrode layers 61 and 62 having a conductive oxide as a main component is formed. As the conductive oxide, for example, zinc oxide, indium oxide and tin oxide may be used alone or in mixture thereof. From the viewpoints of electroconductivity, optical characteristics and long-term reliability, indium-based oxides may be used. Among them, those having indium tin oxide (ITO) as a main component may be used. The thickness of each of the transparent electrode layers 61 and 62 may be set to 10 nm or more and 140 nm or less, from the viewpoints of transparency, electroconductivity and reduction of light reflection.

In one or more embodiments, the transparent electrode layers are formed by a dry process (a CVD method or a PVD method such as a sputtering method or an ion plating method). A PVD method such as a sputtering method or an ion plating method may be used for formation of an electrode layer mainly composed of an indium-based oxide. When the electrode layer is formed on both surfaces by a dry process without using a mask, the electrode layer on each of both sides is also formed on the side surfaces and at the peripheral end of the other surface of the photoelectric conversion section due to wraparound during deposition. Accordingly, the electrode layers on both sides are short-circuited, leading to deterioration of the characteristics of the solar cell.

(Method for Foaming First Electrode Layer)

In one or more embodiments of the present invention, the first electrode layer 61 is formed while the peripheral edge of the substrate is in contact with a mask, so that the peripheral edge of the first principal surface forms the electrode layer-non-formed region 615. Accordingly, even when the second electrode layer 62 is formed on the side surfaces and at the peripheral end of the opposite surface in a wraparound manner, an insulating region 401 in which either the first electrode layer or the second electrode layer is not formed exists on the first principal surface of the photoelectric conversion section 40. Owing to existence of the insulating region 401, a short-circuit caused by wraparound during deposition of the electrode layer can be prevented.

In the manufacturing method according to one or more embodiments of the present invention, the first electrode layer 61 is formed by a deposit-up method with the substrate mounted on a mask plate in such a manner that the lower surface is on the first principal surface, i.e., the first conductive silicon-based thin-film 31-formed surface. The configuration on the second principal surface in the substrate that is subjected to the first electrode layer forming step is not particularly limited as long as the first conductive silicon-based thin-film 31 is formed on the first principal surface of the silicon substrate. The silicon-based thin-films 22 and/or 32 are optionally formed on the substrate on the second principal surface. The second electrode layer 62 may be formed on a silicon-based thin-film on the substrate on the second principal surface.

In one or more embodiments, the deposit-up method (face-down method) is a deposition method in which a substrate is disposed in such a manner that the deposition surface of the substrate is on the lower side in a vertical direction, vapor deposition particles flying upward from a vapor deposition source below the substrate are deposited on the substrate. In the deposit-up method, defects resulting from falling of particles deposited in a deposition chamber during deposition can be avoided. When deposition is performed with a substrate mounted on a mask plate having an opening, adhesion between the substrate and the mask plate is improved by the self-weight of the substrate, and therefore vapor deposition particles penetrate from gaps thereby deposited on the substrate tends to be reduced.

FIG. 2 is a schematic perspective view of one form of a mask plate to be used in formation of the first electrode layer. A mask plate 200 has an opening 220 surrounded by a mounting plane 210 and an opening wall surface 213. The shape of the opening is fit to the shape of the substrate, and the size of the opening is smaller than the shape of the substrate. In FIG. 2, the opening 220 has a rectangular shape. When the substrate has a polygonal shape, it is possible that the opening also have a polygonal shape.

The opening edge portion that is a boundary portion between the mounting plane 210 and the opening 220 has a tapered surface 215 forming a certain angle α with the mounting plane 210. When deposition is performed by a dry process with the substrate mounted in such a manner that the first conductive silicon-based thin-film is in contact with the tapered surface of the opening edge portion, vapor deposition particles from the lower part of the opening 220 are deposited at the central part of the substrate, so that the first electroconductive layer is formed.

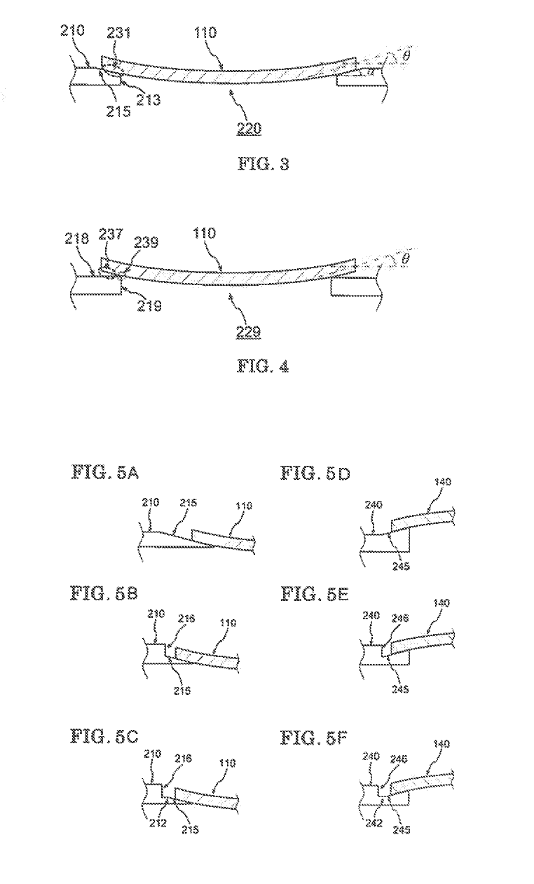

FIG. 3 is a schematic sectional view showing one example of a state in which a substrate 110 is mounted on a mask plate. The substrate 110 is deflected under the self-weight so as to project on the deposition surface (first principal surface) side, and the deflection angle at the peripheral end of the substrate is θ. The mask plate has the tapered surface 215 formed in such a manner that the opening 220 is widened as going from the lower surface toward the upper surface (mounting plane). The taper angle α of the tapered surface is set so as to conform to the deflection angle θ of the substrate. The deflection angle formed under the self-weight is about 1° in the case of a substrate having a thickness of 100 μm and a size of 6 inches, and the deflection angle rapidly increases as the thickness decreases. When the thickness of the substrate is unchanged, the deflection angle increases as the substrate size increases.

FIG. 4 is a schematic sectional view showing a comparative example with a substrate mounted on a mask plate having no tapered surface at the opening edge portion. The substrate 110 deflected under the self-weight is in contact with a corner portion 239 between a mounting plane 218 and an opening wall surface 219 of the mask plate, and an air gap 237 exists between the peripheral edge of the substrate and the mounting plane 218. Vapor deposition particles flying from the lower part of the opening 229 penetrate into the air gap 237 at the peripheral edge of the substrate from a gap between the corner portion 239 of the mask plate and the substrate 110, so that the transparent electrode layer is also deposited at the peripheral edge of the substrate which is covered with the mask plate. When textures are formed on a surface of the substrate 110, a large number of gaps also exist between the substrate and the corner portion of the mask plate, and the substrate and the mask plate are only slightly in contact with each other at the peaks of the projection portions of the textures, so that the amount of deposition due to penetration into the air gap 237 between the peripheral edge of the substrate and the mounting plane 218 increases.

The thickness of the transparent electrode layer formed on the substrate 110 on the opening 220 of the mask plate is almost constant. A region at the central part of the substrate (on the opening of the mask plate), where the transparent electrode layer is formed in a constant thickness, is hereinafter referred to as a “principal formation region”. On the other hand, a mask plate-covered region at the peripheral edge of the substrate has a transition region where the transparent electrode layer is formed due to penetration from a gap between the substrate and the mask plate. In the transition region, at least one of the covering ratio and the thickness of the transparent electrode layer decreases as going from the principal formation region side toward the peripheral end.

For forming an electrode layer-non-formed region at the peripheral edge of the substrate by deposition with using a mask, it is necessary to set the width of the mask-covered region (size of the opening of the mask plate) with consideration given to the width of the transition region. When the air gap between the substrate and the mask plate is large as shown in FIG. 4, the transition region has a large width, and therefore it is necessary to reduce the opening area of the mask by increasing the width of the region covered by the mask. As a result, the area of an electrode layer principal formation region decreases, so that the effective power generation area of the solar cell tends to decrease, leading to deterioration of power generation efficiency.

As shown in FIG. 3, on the other hand, when the tapered surface 215 conforming to the deflection angle of the substrate exists at the opening edge portion of the mask plate, and the peripheral edge of the substrate is placed on the tapered portion, the shape of a peripheral edge 231 of the substrate 110 conforms to the shape of the mask plate, and therefore the air gap becomes small. Accordingly, an area where deposition occurs due to penetration from a gap between the substrate and the mask plate, i.e., a transition region, in the mask plate-covered region, can be made small. In one or more embodiments of the present invention, as just described, the mask plate has a tapered surface at a part that is in contact with a deposition surface at the opening edge portion, and the tapered surface conforming to the deflection angle at the peripheral end of the silicon substrate. Therefore, penetration of vapor deposition particles to the peripheral edge of the substrate is reduced, so that the width of the transition region can be decreased (e.g., less than 1.5 mm). Accordingly, the effective power generation area of the solar cell can be increased to improve conversion efficiency.

In the method according to one or more embodiments of the present invention, a tapered surface conforming to the deflection angle of the substrate exists at the opening edge portion of the mask plate, and therefore alignment in mounting of the substrate on the mask plate is facilitated, so that productivity can be improved. Since the width of the transition region of the electrode layer decreases, and alignment is facilitated, deposition of an electrode on the peripheral end of the substrate is suppressed to contribute to suppression of defects such as a short-circuit between front and back surfaces. Further, since the mask plate and the substrate are in contact with each other on the tapered surface, the substrate can be inhibited from being scratched during mounting or removal of the substrate. Particularly, when the thickness of the silicon substrate is small, chipping of the peripheral edge of the substrate and cracking from the peripheral end of the substrate tend to easily occur in mounting of the substrate on the mask plate. By providing a tapered surface at an opening edge portion of the mask plate, chipping, cracking and the like can be suppressed. The substrate is mounted on the tapered surface of the mask plate, there are a large number of contact points between the mask plate and the substrate, and thus the electrode layer is formed in a state in which local stress at the peripheral edge of the substrate is small. Accordingly, strain at the interface of the electrode layer is small, so that interface adherence is improved, and thus the open circuit voltage (Voc) of the solar cell tends to increase.

Since a general mask plate is made of metal and has high thermal conductivity, the atmospheric temperature in the vicinity of the opening edge portion of the mask plate tends to be higher than the atmospheric temperature in the vicinity of the opening of the mask plate during deposition of the electrode layer. In the method according to one or more embodiments of the present invention, the air gap between the substrate and the peripheral edge of the substrate is small, and therefore during deposition of the electrode layer, the temperature tends to be higher at the peripheral edge of the substrate than at the central portion of the substrate. It is supposed that when the substrate temperature increases, a conductive oxide is easily crystallized, and therefore the transition region where the transparent electrode layer is formed in proximity to the mask plate has a higher degree of crystallinity as compared to the electrode layer principal formation region. Accordingly, ingress of moisture from the peripheral edge of the substrate in the solar cell, or the like is suppressed, and thus durability of the solar cell is expected to be improved. Extent of crystallinity can be determined by immersing the substrate in 10% hydrochloric acid at 25° C. for a predetermined time, then observing a surface shape at a magnification of 50,000 using a scanning electron microscope (SEM), and examining a difference in change of the surface state. The immersion time until occurrence of a difference in surface state becomes longer as the degree of crystallinity increases.

The shape of the opening edge portion of the mask plate is not limited to the form illustrated in FIG. 2 and FIG. 3 as long as a tapered surface is formed on at least a part of the opening edge portion. For example, the mask plate may have a shape in which the opening wall surface does not exist, and the whole of the opening edge portion is formed by the tapered surface 215 as shown in FIG. 5A. A wall surface 216 forming a right angle or a predetermined angle with the mounting plane 210 may be formed on the outer periphery of the tapered surface 215 as shown in FIG. 5B. A horizontal surface 212 may be formed between the tapered surface 215 and the wall surface 216 as shown in FIG. 5C. Particularly, when the mask plate has the wall surface 216 on the outer periphery of the tapered surface 215 as shown in FIG. 5B and FIG. 5C, alignment in mounting of the substrate on the mask plate is facilitated.

In one or more embodiments, when a substrate 140 is deflected so as to project at the upper surface, the tapered surface 245 of the opening edge portion of the mask plate is formed so as to conform to the shape of the substrate 140 as shown in FIGS. 5D to 5F. The electrode layer may be formed on the first principal surface side with the substrate deflected so as to project on the second principal surface side due to stress on the interface of the electrode layer, when, for example, the electrode layer on the second principal surface of the substrate is formed beforehand. A wall surface 246 and a horizontal surface 242 may be formed on the outer periphery of the tapered surface 245 as shown in FIGS. 5E and 5F, even in the case where the tapered surface of the opening edge portion of the mask plate is formed so as to conform to the deflection angle of an upward projecting substrate, as just described.

The taper angle of the tapered surface, i.e., the angle α formed by the mounting plane 210 or 240 and the tapered surface 215 or 245 may be close to the deflection angle θ at the peripheral end of the substrate. Specifically, the taper angle α may be 0.5 times to 2 times, or 0.7 times to 1.5 times as large as the deflection angle θ. The deflection angle θ is not particularly limited, and it is generally in the range of about 0.1° to 100.

As described above, the first electrode layer 61 formed by a deposit-up method on the mask plate has a transition region 613 on the outer periphery of a principal formation region 611, and the outer periphery of the transition region 613 is the non-formed region 615.

(Second Electrode Layer)

In one or more embodiments of the heterojunction solar cell, the second electrode layer 62 is formed on the second principal surface (conductive silicon-based thin-film 32) of the photoelectric conversion section 40. Formation of the second electrode layer may be performed either before or after the formation of the first electrode layer. As shown in FIG. 1, the electrode layer-non-formed region 615 exists at the peripheral edge of the first principal surface. Therefore, the insulating region 401, which is not provided with either the first electrode layer or the second electrode layer, is formed at the peripheral edge of the first principal surface, even in the case where the second electrode layer 62 is formed over the second principal surface of the photoelectric conversion section 40 to the peripheral end, and also formed on the side surfaces of the photoelectric conversion section and at the peripheral end of the first principal surface of the photoelectric conversion section in a wraparound manner.

As in the case of formation of the first electrode layer, the second electrode layer may be formed while the peripheral edge of the second principal surface is covered with a mask. In this case, wraparound to the side surfaces and the peripheral end of the first principal surface of the photoelectric conversion section can be prevented, and therefore a short-circuit between the first electrode layer and the second electrode layer can be more reliably prevented.

On the other hand, in one or more embodiments of the present invention, the width of the transition region of the first electrode layer is small, and therefore a short-circuit between the first electrode layer and the second electrode layer can be prevented even when the second electrode layer 62 is formed without using a mask, and thus wraparound of the second electrode layer to the side surfaces and the peripheral end of the first principal surface of the photoelectric conversion section occurs. When a mask is used only in formation of the first electrode layer, production efficiency of solar cells is improved because the number of alignments of the mask decreases by half as compared to a case where a mask is used in formation of both of the first and second electrode layers. In this embodiment, carrier collection efficiency at the peripheral edge of the photoelectric conversion section is improved because an insulating region does not exist on the second principal surface, and the second electrode layer is formed at the peripheral end. Accordingly, as compared to a case where the photoelectric conversion section has an insulating region on both surfaces thereof production efficiency is improved, and improvement of conversion efficiency can be expected.

In one or more embodiments, when the second electrode layer is formed on the first principal surface in a wraparound manner, the width of the insulating region 401 on the first principal surface, i.e., the shortest distance between the end portion of the transition region of the first transparent electrode layer and the second transparent electrode layer is required to be larger than 0. The width of the insulating region may be less than 1.5 mm.

[Collecting Electrode]

In one or more embodiments of the heterojunction solar cell, a metal collecting electrode is formed on each of the transparent electrode layers 61 and 62 for effectively extracting photogenerated carriers. The collecting electrode on the light-receiving side is formed in a specific pattern shape. The collecting electrode on the back side may be formed in a pattern shape, or formed on substantially the whole surface of the transparent electrode layer. In the embodiment shown in FIG. 1, a patterned collecting electrode 7 is formed on the transparent electrode layer 61 on the light-receiving side, and a back side metal electrode layer 8 is formed on the whole surface of the back side transparent electrode layer 62. Examples of the method for forming a metal electrode layer on the whole surface of a transparent electrode layer include dry processes such as various kinds of PVD methods and CVD methods, application of a paste, and a plating method. For the back side metal electrode layer, it is possible to use a material which has a high reflectivity of light having a wavelength in a near infrared to infrared range and which has high electroconductivity and chemical stability. Examples of the material having the above-mentioned properties include silver, copper and aluminum.

In one or more embodiments, the patterned collecting electrode is formed by a method of applying an electroconductive paste, a plating method, or the like. When an electroconductive paste is used, the collecting electrode is formed by ink-jetting, screen printing, spraying or the like. Screen printing may be used, from the viewpoint of productivity. In screen printing, a process of applying an electroconductive paste containing metallic particles and a resin binder by screen printing may be used.

When the patterned collecting electrode is formed by a plating method, it is possible that a metal seed 71 in a pattern shape be formed on the electrode layer, and a metal electrode 72 be formed by a plating method with the metal seed as an origination point. An insulating layer 9 may be formed on the transparent electrode layer 61 for suppressing deposition of the metal electrode on the transparent electrode layer 61.

The insulating layer 9 may be formed over the first principal surface to the peripheral end thereof. When the insulating layer is formed over the first principal surface to the peripheral end (i.e., the insulating layer is formed over the whole region of the first principal surface), the insulating layer also exists on the electrode layer-non-formed region 615, and therefore the photoelectric conversion section 40 can be protected chemically and electrically from a plating solution in formation of the metal electrode 72 by a plating method. Accordingly, diffusion of impurities etc. in the plating solution to the crystalline silicon substrate can be suppressed, and thus improvement of long-term reliability of the solar cell can be expected.

The insulating layer 9 may also be formed on the side surfaces of the photoelectric conversion section. At the time of connecting a plurality of solar cells through an interconnector to modularize the solar cells, a short-circuit with the interconnector is prevented when the insulating layer is formed on the side surface, even in the case where the side surface of the photoelectric conversion section and the interconnector come into contact with each other. Therefore conversion efficiency of a solar cell module can be improved.

In one or more embodiments, for forming the metal electrode 72 on the metal seed 71 by a plating method, it is necessary to bring the metal seed into conduction with the plating solution. Accordingly, it is necessary to provide an aperture 9h in the insulating layer 9 on the metal seed 71. Examples of the method for forming an aperture in the insulating layer include a method in which the insulating layer is patterned using a resist. An aperture may be formed in the insulating layer by a method such as laser irradiation, mechanical boring or chemical etching.

In one or more embodiments, besides the method described above, the following technique etc. can be employed as a method for forming a plating metal electrode via the aperture in the insulating layer.

An insulating layer is formed on a transparent electrode, a groove extending through the insulating layer then is provided to expose a surface or side surface of a transparent electrode layer, a metal seed is deposited on the exposed surface of the transparent electrode layer by photoplating etc., and a metal electrode layer is then formed by plating with the metal seed as an origination point (see Japanese Patent Laid-open Publication No. 2011-199045).

An insulating layer is formed on a metal seed having irregularities, so that the insulating layer becomes discontinuous, resulting in formation of an aperture. A metal electrode is formed with the aperture as an origination point (International Publication No. WO 2011/045287).

After or during formation of an insulating layer on a metal seed containing a low-melting-point material, the low-melting-point material is thermally fluidized by heating to form an aperture in the insulating layer on the metal seed, and a metal electrode is formed with the aperture as an origination point (International Publication No. WO 2013/077038).

A self-organized monomolecular film is formed as an insulating layer, and the self-organized monomolecular film is then separated and removed to form an aperture in the insulating layer (the metal seed is exposed). A metal electrode is formed with the exposed metal seed as an origination point. Since the self-organized monomolecular film is formed on a transparent electrode layer, deposition of the metal electrode on the transparent electrode layer is suppressed (International Publication No. WO 2014/097829).

These methods are more advantageous in terms of material costs and process costs because it is not necessary to use a resist. By providing the metal seed having low resistance, contact resistance between the transparent electrode layer and the collecting electrode can be reduced.

In one or more embodiments of the present invention, the electrode layer is formed while the mask plate and the substrate are in contact with each other at a tapered surface, and scratching of the substrate, cracking of the substrate at the end surface, and so on during mounting or removal of the substrate are suppressed, resulting in improvement of coverage of the insulating layer formed on the electrode layer (particularly the transition region) at the peripheral edge of the substrate and on the electrode layer-non-formed region. Accordingly, deposition of a plating metal on an undesired area such as the peripheral edge of the substrate tends to be suppressed.

Although an example in which a transparent electrode layer on the light-receiving side of a heterojunction solar cell is formed with a mask has been mainly described above, the transparent electrode layer on the light-receiving side may be formed on the whole surface without using a mask while the transparent electrode layer on the back side is formed with using a mask. One or more embodiments of the present invention are applicable not only to heterojunction solar cells but to various kinds of solar cells including an electrode layer and a collecting electrode on a photoelectric conversion section including a silicon substrate.

The solar cell according to one or more embodiments of the present invention may be sealed by a sealing material and modularized when put into practical use. Modularization of the solar cell is performed by an appropriate method. For example, by connecting a bus bar via an interconnector such as a TAB to a collecting electrode, a plurality of solar cells are connected in series or in parallel, and sealed by a sealing material and a glass plate to thereby perform modularization.

### DESCRIPTION OF REFERENCE CHARACTERS

1 crystalline silicon substrate
21, 22 intrinsic silicon-based thin-film
31, 32 conductive silicon-based thin-film
61, 62 electrode layer
7 collecting electrode
71 seed layer
72 metal electrode
8 back electrode
9 insulating layer
9h aperture
40 photoelectric conversion section
101 heterojunction solar cell
110, 130 substrate
200 mask plate
210, 230 mounting plane
215, 245 tapered surface
401 insulating region
611 principal formation region
613 transition region
615 electrode layer non-formed region

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

1. A method for manufacturing a solar cell comprising a first electrode layer on a first principal surface of a photoelectric conversion section including a crystalline silicon substrate, the method comprising:
forming the first electrode layer on the first principal surface side of the crystalline silicon substrate, wherein
the first electrode layer is formed by a deposit-up method with the crystalline silicon substrate mounted in such a manner that an opening edge portion of a mask plate having an opening is in contact with the first principal surface side of the crystalline silicon substrate, thereby preventing the first electrode layer from being deposited on a peripheral end of the first principal surface, and
the opening edge portion of the mask plate has a tapered surface at a part that is in contact with the first principal surface side of the crystalline silicon substrate, the tapered surface conforming to a deflection angle at a peripheral end of the crystalline silicon substrate.

2. The method according to claim 1, wherein the forming the first electrode layer is carried out with the crystalline silicon substrate deflected so as to project on the first principal surface side, and
the tapered surface of the opening edge portion of the mask plate is formed in such a manner that the opening is widened as going from a lower surface toward a mounting plane of the mask plate.

3. The method according to claim 1, wherein the deflection angle θ of the silicon substrate at the peripheral end is 0.1° to 10°, and an angle α formed by a mounting plane of the mask plate and the tapered surface is 0.5θ to 2θ.

4. The method according to claim 1, wherein a thickness of the crystalline silicon substrate is 10 to 150 μm.

5. The method according to claim 1, wherein in the forming the first electrode layer, a transition region in which at least one of a covering ratio and a thickness of the first electrode layer decreases as going from the opening of the mask plate toward the peripheral end of the crystalline silicon substrate is formed in a mask plate-covered region of the first principal surface side of the crystalline silicon substrate, and
a width of the transition region is more than 0 and less than 1.5 mm.

6. The method according to claim 1, further comprising, in the following order:
forming a pattern-shaped metal seed on the first electrode layer;
forming an insulating layer on the entire surface of the first electrode layer; and
forming a metal electrode, which is in conduction with the metal seed, by a plating method, wherein
the metal electrode is in conduction with the metal seed through an aperture provided in the insulating layer.

7. The method according to claim 1, wherein
in the solar cell, the crystalline silicon substrate is a single-crystalline silicon substrate having a textured surface,
the photoelectric conversion section includes a conductive silicon-based thin-film on both surfaces of the single-crystalline silicon substrate, and
the first electrode layer is a transparent electrode layer, and wherein
the method further comprises forming a second electrode layer on a second principal surface of the crystalline silicon substrate, and
in the forming the first electrode layer, the first electrode layer is not formed at the peripheral end of the first principal surface of the photoelectric conversion section, thereby the first electrode layer and the second electrode layer in the solar cell being insulated from each other.

8. The method according to claim 7, wherein in the forming the second electrode layer, the second electrode layer is also formed at a peripheral end of the second principal surface side and a side surface of the crystalline silicon substrate.

9. The method according to claim 8, wherein in the forming the second electrode layer, the second electrode layer is also formed at the peripheral end of the first principal surface side of the crystalline silicon substrate, and
the shortest distance between the first electrode layer and the second electrode layer is more than 0 and less than 1.5 mm on the first principal surface side of the crystalline silicon substrate.

10. A method for manufacturing a solar cell module, comprising the method of: manufacturing a solar cell according to claim 1 followed by sealing the solar cell with a sealing material.

11. A solar cell comprising:
a photoelectric conversion section including a conductive silicon-based thin-film on both surfaces of a single-crystalline silicon substrate having a surface texture;
a first transparent electrode layer provided on a first principal surface of the photoelectric conversion section; and
a second transparent electrode layer provided on a second principal surface of the photoelectric conversion section, wherein
the second transparent electrode layer is also formed at a peripheral end of the second principal surface and a side surface of the photoelectric conversion section and at a peripheral end of the first principal surface of the photoelectric conversion section,
the first transparent electrode layer is not formed at the peripheral end of the first principal surface of the photoelectric conversion section, thereby the first transparent electrode layer and the second transparent electrode layer being insulated from each other,
the first transparent electrode layer includes a principal formation region at a central part of the first principal surface, and a transition region in which at least one of a covering ratio and a thickness decreases as going from the principal formation region toward the peripheral end of the photoelectric conversion section, and
in the first transparent electrode layer, crystallinity in the transition region is larger than crystallinity of the transparent electrode in the principal formation region.

12. The solar cell according to claim 11, wherein a width of the transition region is more than 0 and less than 1.5 mm.

13. The solar cell according to claim 11, wherein the shortest distance between the first electrode layer and the second electrode layer is more than 0 and less than 1.5 mm on the first principal surface side of the crystalline silicon substrate.

14. The solar cell according to claim 11, wherein a thickness of the silicon substrate is 10 to 150 μm.

15. The solar cell according to claim 11, further comprising:
a pattern-shaped metal seed on the first transparent electrode layer;
an insulating layer formed on the entire surface of the first transparent electrode layer; and
a metal electrode, wherein
the metal electrode is in conduction with the metal seed through an aperture provided in the insulating layer.

16. A solar cell module, wherein the solar cell according to claim 11 is sealed by a sealing material.
